(19) United States
(12) Patent Application Publication
(10) Pub. No.: US 2004/0190269 A1
(43) Pub. Date: Sep. 30, 2004

(54) PCB fusing trace arrangement for motor drive applications

(75) Inventor: Jonn E. Makaran, London (CA)

Correspondence Address: Elsa Keller, Intellectual Property Department, SIEMENS CORPORATION, 170 Wood Avenue South, Iselin, NJ, 08830, US

(73) Assignee: Siemens VDO Automotive Inc.

(21) Appl. No.: 10/807,086

(22) Filed: Mar. 23, 2004

Related U.S. Application Data
(60) Provisional application No. 60/456,523, filed on Mar. 24, 2003.

(51) Int. Cl. H05K 7/02

(52) U.S. Cl. 361/748

(57) ABSTRACT

A method provides, on a printed circuit board 16, at least a first and a second printed circuit board fuse trace A, B placed in parallel with each other in a main current carrying path 18. In a normal operating condition, it is ensured that 1) all of the traces carry a portion of a load current and 2) the traces are configured to prevent opening of the traces in the normal operating condition. When a fault condition occurs, it is ensured that the first trace A opens before a resistance thereof increases so as to divert more of a load current to the second trace B, thereby causing the second trace B to open after opening of the first trace A.

This application is based on U.S. Provisional Application No. 60/456,523, filed on Mar. 24, 2003 and claims the benefit thereof for priority purposes.

### BACKGROUND OF THE INVENTION

In motor drive applications, it is commonly desired to have a fusing arrangement as a failsafe to protect the wire harness from damage in the event that there is a failure of one or more power electronic devices that are connected directly to the power supply. In the case of brushless motors, failures of this type can cause a direct short across the positive and negative supply of the motor.

Traditional fusing arrangements for motor loads use slow blow protection devices to prevent nuisance tripping. Fast blow fuses are typically not used to perform this function due to their propensity to false trip under regular running conditions.

FIG. 1 shows a typical fault current profile for a brushless motor that has experienced a direct short across the positive and negative battery supply. As shown, there is an initial period of high current followed by a decrease in the fault current to approximately the maximum running current as the motor winding resistance increases due to heat. In such a condition, a slow blow fuse cannot provide protection, since the period of high current is too short to cause opening of the fuse.

A fast blow fuse cannot be used to protect against fault currents of this type due to the fact that the time for a fast blow fuse to open can vary significantly in addition to the fact that fault current value is approximately equal to the RMS value of the motor running current.

Thus, there is a need to provide an improved fusing trace arrangement for a printed circuit board (PCB).

### SUMMARY OF THE INVENTION

An object of the invention is to fulfill the need referred to above. In accordance with the principles of the present invention, this objective is achieved by a method providing a fusing trace arrangement on a printed circuit board. The method provides, on a printed circuit board, at least a first and a second printed circuit board fuse trace placed in parallel with each other in a main current carrying path. In a normal operating condition, it is ensured that 1) all of the traces carry a portion of a load current and 2) that the traces are configured to prevent opening thereof. When a fault condition occurs, it is ensured that the first trace opens before a resistance thereof increases so as to divert more of a load current to the second trace, thereby causing the second trace to open after opening of the first trace.

In accordance with another aspect of the invention, a fusing trace arrangement on a printed circuit board is provided. The arrangement includes a circuit board, and a first group and a second group of fuse traces. The first and second groups are placed in parallel with each other in a main current carrying path on the circuit board. Each of the first and second groups includes at least first and second traces arranged in parallel and, in a normal operating condition, 1) all of the traces are constructed and arranged to carry a portion of a load current and 2) the traces are configured to prevent opening thereof. When a fault condition occurs, the first trace of each group is constructed and arranged to open before a resistance thereof increases so as to divert more of the load current to the remaining traces of the associated group, thereby causing the remaining traces of the associated group to open sequentially.

Other objects, features and characteristics of the present invention, as well as the methods of operation and the functions of the related elements of the structure, the combination of parts and economics of manufacture will become more apparent upon consideration of the following detailed description and appended claims with reference to the accompanying drawings, all of which form a part of this specification.

### BRIEF DESCRIPTION OF THE DRAWINGS

The invention will be better understood from the following detailed description of the preferred embodiments thereof, taken in conjunction with the accompanying drawings, wherein like reference numerals refer to like parts, in which:

FIG. 1 is typical fault current profile for a brushless motor that has experienced a direct short across the positive and negative battery supply.

FIGS. 2a and 2b each show groups of traces arranged in parallel on a printed circuit board in accordance with the invention.

FIGS. 3a and 3b each show a group of traces on a printed circuit board in accordance with the invention.

FIGS. 4a-4c each show an embodiment of a trace shape in accordance with the invention to optimize operational and fault current behavior.

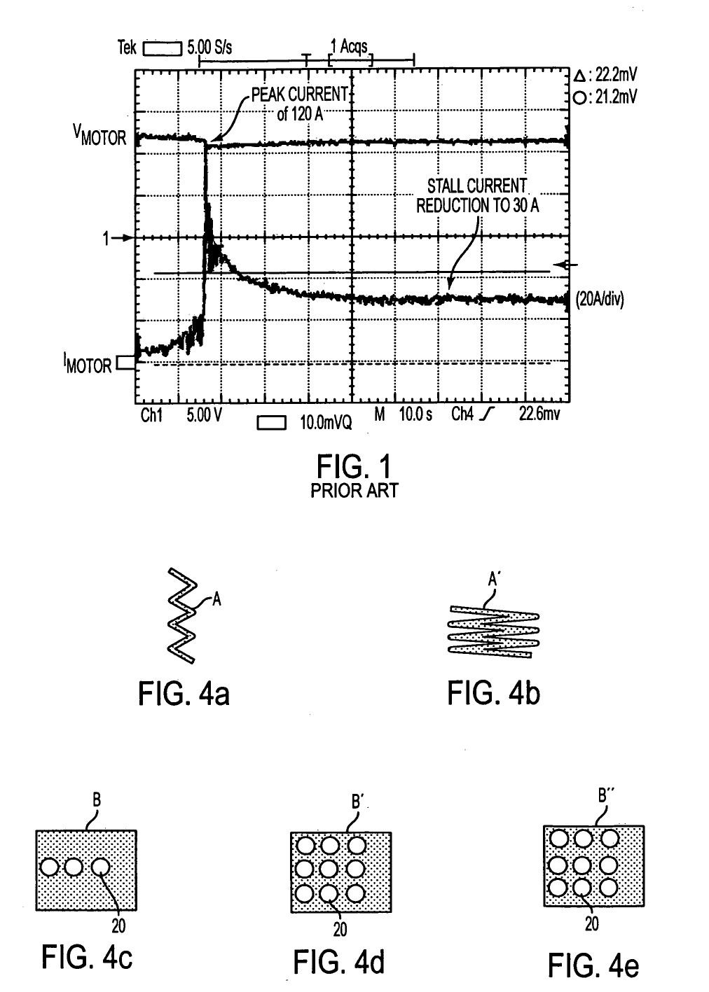

### DETAILED DESCRIPTION OF THE EXEMPLARY EMBODIMENT

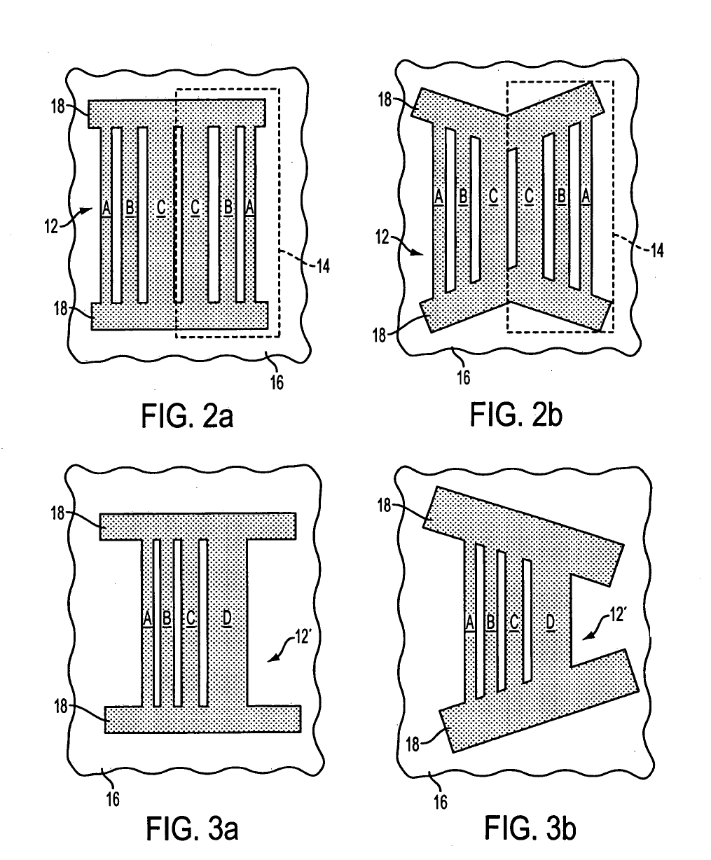

In accordance with the invention, an improved PCB fusing arrangement is shown, for example, in FIGS. 2a-2b and FIGS. 3a-3b in accordance with the principles of the invention. FIG. 2a, shows a first group 12 of traces A, B, C and a second group 14 of traces C, B, A. The traces A, B, C, are arranged in parallel with each other and the groups 12 and 14 are arranged in parallel on a circuit board 16 in the main current carrying path 18. In FIG. 2a, all the traces A, B, C have the same length. FIG. 2b shows traces A, B and C having different lengths. In each of FIGS. 2a, and 2b, it can be seen that the width of the traces is as follows: Width C>Width B>Width A.

FIG. 3a shows another group 12′ of traces A, B, C and D of the invention with each trace having the same length. FIG. 3b shows traces A, B, C and D having different lengths. In each of FIGS. 3a, and 3b, it can be seen that the width of the traces is as follows: Width D>Width C>Width B>Width A. The traces are composed of any conductive metal.

Under normal running conditions, all of the traces (e.g., A, B, C) carry a portion of the load current, and are sized to prevent opening of the traces under normal running conditions. The narrower (width) and longer the trace, the higher the resistance thereof.

When a fault current occurs, trace A of each group 12, 14 is configured to open before the resistance thereof can increase so as to divert more of the operating current through the remaining traces of the associated group. Once trace A opens, the current density through the remainder of the traces (B, C, D, etc.) of the associated group increases so as to open trace B. Once trace B opens, the current density (current/area) through trace C increases, so it too opens, and so on until all traces of a group are opened sequentially.

It is understood that the configuration of the traces A, B, C, D, etc., must be optimized so as to ensure they do not open across the entire operating voltage and temperature range of the motor. In order to achieve this, a good understanding of the thermodynamics of the system, as well as how the shapes of the traces effect thermodynamics must be realized. For example, a toothed-shape can be used for the narrow width traces or, a solid trace with holes of varying diameters and locations can be used. Proposed toothed-shape traces A, A′ are shown in FIGS. 4a and 4b, respectively. Proposed solid traces B, B′, B″ with through-holes 20 are shown in FIGS. 4c, 4d and 4e, respectively. It is noted that the possibility for trace options is not limited to these shapes; however, the general premise is that once a current path with a higher resistance fails, the remainder of the current through the traces will cause remaining traces to fail.

It should be noted that different trace shapes could be used with each other to optimize the operational/fault current behavior.

Thus, the fuse arrangements of the embodiments are useful in motor drive applications, such as automotive applications, as a failsafe to protect the conventional wire harness (not shown) from damage in the event that there is a failure of one or more power electronic devices that are connected directly to the power supply.

The foregoing preferred embodiments have been shown and described for the purposes of illustrating the structural and functional principles of the present invention, as well as illustrating the methods of employing the preferred embodiments and are subject to change without departing from such principles. Therefore, this invention includes all modifications encompassed within the spirit of the following claims.

What is claimed is:

1. A method of providing a fusing trace arrangement on a printed circuit board, the method including the steps of:
providing, on a printed circuit board, at least a first and a second printed circuit board fuse trace placed in parallel with each other in a main current carrying path,
ensuring that in a normal operating condition, 1) all of the traces carry a portion of a load current and 2) the traces are configured to prevent opening thereof, and
ensuring that when a fault condition occurs, the first trace opens before a resistance thereof increases so as to divert more of a load current to the second trace, thereby causing the second trace to open after opening of the first trace.

2. The method of claim 1, wherein the first trace has a width less than the second trace.

3. The method of claim 1, wherein the traces are constructed and arranged such that the first trace has a resistance higher than the second trace.

4. The method of claim 1, wherein a length of the first trace is the same as a length of the second trace.

5. The method of claim 1, wherein a length of the first trace is greater than a length of the second trace.

6. The method of claim 2, wherein a length of the first trace is greater than a length of the second trace.

7. The method of claim 1, wherein the traces are arranged in parallel with each other.

8. A method of providing a fusing trace arrangement on a printed circuit board, the method including the steps of:
providing, on a printed circuit board, a first group of traces and a second group of traces, each group of traces having at least first and second printed circuit board fuse traces arranged in parallel, the first group or traces being in parallel with the second group of traces in a main current carrying path,
ensuring that in a normal operating condition, 1) all of the traces carry a portion of a load current and 2) the traces are configured to prevent opening thereof, and
ensuring that when a fault condition occurs, the first trace of each group of traces opens before a resistance thereof increases so as to divert more of a load current to remaining traces of the associated group, thereby causing the remaining traces of the associated group to open sequentially.

9. The method of claim 8, wherein the first trace of each group has a width less than the second trace of the associated group.

10. The method of claim 8, wherein the traces each group are constructed and arranged such that the first trace has a resistance higher than the second trace.

11. The method of claim 8, wherein the traces of each group are constructed and arranged such that traces having a resistance higher than other traces of the group open prior to the other traces.

12. The method of claim 8, wherein a length of the first trace is the same as a length of the second trace.

13. The method of claim 8, wherein a length of the first trace is greater than a length of the second trace.

14. The method of claim 9, wherein a length of the first trace is greater than a length of the second trace.

15. A fusing trace arrangement on a printed circuit board, the arrangement comprising:
a circuit board, and
a first group and a second group of fuse traces, the first and second groups being placed in parallel with each other in a main current carrying path on the circuit board,
wherein, each of the first and second groups includes at least first and second traces arranged in parallel and, in a normal operating condition, 1) all of the traces are constructed and arranged to carry a portion of a load current and 2) the traces are configured to prevent opening thereof, and
wherein, when a fault condition occurs, the first trace of each group is constructed and arranged to open before a resistance thereof increases so as to divert more of the load current to the remaining traces of the associated group, thereby causing the remaining traces of the associated group to open sequentially.

16. The arrangement of claim 15, wherein the first trace of each group has a width less than the second trace of the associated group.

17. The arrangement of claim 15, wherein at least one trace of each group has a serpentine configuration.

18. The arrangement of claim 15, wherein the traces each group are constructed and arranged such that the first trace has a resistance higher than the second trace.

19. The arrangement of claim 15, wherein the traces of each group are constructed and arranged such that traces having a resistance higher than other traces of the group open prior to the other traces.

20. The arrangement of claim 15, wherein a length of the first trace is the same as a length of the second trace.

21. The arrangement of claim 15, wherein a length of the first trace is greater than a length of the second trace.

22. The arrangement of claim 16, wherein a length of the first trace is greater than a length of the second trace.

23. The arrangement of claim 15, wherein at least one trace of each group is a solid trace with holes there through.
